(19) United States
(12) Patent Application Publication
(10) Pub. No.: US 2017/0254935 A1
(43) Pub. Date: Sep. 7, 2017

(54) COLOR FILTER SUBSTRATE AND METHOD OF MANUFACTURING THE SAME, AND DISPLAY PANEL

(71) Applicant: BOE Technology Group Co., Ltd., Beijing (CN)

(72) Inventor: Iguchi Shinsuke, Beijing (CN)

(21) Appl. No.: 15/207,542

(22) Filed: Jul. 12, 2016

(30) Foreign Application Priority Data
Mar. 4, 2016 (CN) 201610124572.X

(51) Int. Cl. G02B 5/20; H01L 51/56; H01L 51/52; G02B 1/14; H01L 27/32

(52) U.S. Cl. CPC G02B 5/201; G02B 1/14; H01L 27/3244; H01L 27/322; H01L 51/5284; H01L 51/56; H01L 51/5253; H01L 2227/323

(57) ABSTRACT

A color filter substrate, a method of manufacturing the color filter substrate and a display panel having the color filter substrate are disclosed. The color filter substrate includes: a base substrate; a first color filter located at one side of the base substrate; and a black matrix located at a side of the color filter away from the base substrate. The black matrix covers a portion of the color filter.

### CROSS-REFERENCE TO RELATED APPLICATION

This application claims benefits of Chinese Patent Application No. 201610124572.X filed on Mar. 4, 2016 in the State Intellectual Property Office of China, a whole disclosure of which is incorporated herein by reference.

### BACKGROUND

Field of the Invention

Embodiments of the present invention relate to the field of display technology, specifically, to a color filter substrate and a method of manufacturing the same, and a display panel having the color filter substrate.

Description of the Related Art

As shown in FIG. 1, in a top-emission organic light-emitting diode (OLED) display panel, each pixel in an array substrate 2 is provided with an organic light-emitting diode 21 served as light-emitting component for emitting white light towards a color filter substrate 1 disposed opposite to the array substrate 2. The pixels are separated by a pixel defining layer. Each pixel in the color filter substrate 1 is provided with a color filter 11 having a respective color and disposed on a base substrate 19, such that light passing the color filter is converted into light having a desired color. A black matrix 12 is disposed between pixels. The black matrix 12 is formed prior to the color filter 11, such that a part of the color filter 11 may be overlapped with the black matrix 12 and may be arranged above the black matrix 12. To protect the color filter 11 and the black matrix 12, they may be covered by an overcoat or a protective layer.

Due to restriction from manufacturing process, there will certainly be a gap of several microns or tens of microns (for example, 5 μm to 20 μm) existing between the color filter 11 and the organic light-emitting diode 21. The organic light-emitting diode 21 emits light towards all directions, and a reflective layer is disposed under the organic light-emitting diode 21, so that the light emitted downwards will be reflected back. Therefore, light emitted from the organic light-emitting diode 21 of each pixel will be emitted to color filters 11 of other pixels. Obviously, if the light exits from the other pixels, a light leakage may occur, and, a light mixing may occur if the other pixels having a different color. To prevent light leakage, it has to ensure that a total reflection will occur when light is emitted to color filters 1 of other pixels. That is, it has to ensure that the light (the two outmost light beam shown in the figure) emitted to other pixels is sufficiently inclined. And that is to say, the black matrix 12 shall be able to shield all the light that is emitted towards respective regions of color filter 1 aligned with other pixels and that will not be totally reflected, i.e., the light that is not sufficiently inclined. To ensure the shielding effect of the black matrix 12, areas of pixels should be reduced and an area of the black matrix 12 should be enlarged as much as possible. However, this may reduce an area of an actual light-emitting region and increase power consumption. In one word, there is no efficient way to solve the problem of light leakage in prior arts.

### SUMMARY

The present invention has been made to overcome or alleviate at least one aspect of the above mentioned disadvantages.

Accordingly, it is an object of the present invention to provide a color filter substrate, a method of manufacturing the color filter substrate and a display device having the color filter substrate.

According to an aspect of the present invention, there is provided a color filter substrate.

In an exemplary embodiment, the color filter substrate may comprise: a base substrate; a first color filter located on a side of the base substrate; and a black matrix located on a side of the color filter facing away from the base substrate. The black matrix covers a portion of the first color filter.

In a further embodiment, the color filter substrate may further comprise a second color filter, and the second color filter is arranged adjacent to the first color filter and has a color different from that of the first color filter.

In a further embodiment, the first color filter and the second color filter may be spaced apart from each other with a gap therebetween, and the black matrix is configured to cover the gap and a portion of the second color filter.

In a further embodiment, the color filter substrate may further comprise a protective layer covering the first color filter, and the black matrix is located on a side of the protective layer away from the base substrate. In an alternative embodiment, the protective layer may cover the first color filter and the black matrix.

According to another aspect of the present invention, there is provided a display panel.

In an exemplary embodiment, the display panel may comprise a color filter substrate according to any of the above embodiment and an array substrate disposed opposite to the color filter substrate. The color filter substrate is configured such that the side of the color filter substrate provided with the black matrix faces the array substrate and the other side of the color filter substrate opposite to the surface provided with the black matrix is a light exiting surface of the display panel.

In a further embodiment, the display panel may comprise an organic light-emitting diode display panel, and the array substrate comprises an organic light-emitting diode located on a side of the array substrate facing the color filter substrate and configured for emitting light towards the color filter substrate.

According to a further aspect of the present invention, there is provided a method of manufacturing a color filter substrate.

In an exemplary embodiment, the method may comprise: forming a color filter on a base substrate; and forming a black matrix on the base substrate such that the black matrix covers a portion of the color filter.

In a further embodiment, the method may further comprise forming a protective layer after the color filter is formed and before the black matrix is formed. In an alternative embodiment, the method may further comprise forming a protective layer after the black matrix is formed.

In the color filter substrate according to the embodiments, the black matrix is located above the color filter, thus, a portion of the black matrix is farther away from the base substrate than the color filter. Therefore, in the case that all components have the same thicknesses and sizes, a distance between the black matrix and the array substrate is reduced. In such a manner, degree of angle at which light emitted by the organic light-emitting diode is shielded by the black matrix on both sides thereof is increased, such that light emitted by the organic light-emitting diode towards regions of the color filter corresponding other pixels will be totally reflected much easier, and a range of an angle at which light emitted by the organic light-emitting diode exits from the region of the color filter corresponding to the organic light-emitting diode is enlarged. Therefore, the color filter substrate may prevent light leakage and light mixing by simply changing a relative position of the black matrix and the color filter. Moreover, an actual light exiting area may be increased, and in turn, light exiting efficiency is improved, power consumption is reduced, and display quality is improved.

### BRIEF DESCRIPTION OF THE DRAWINGS

The above and other features of the present invention will become more apparent by describing in detail exemplary embodiments thereof with reference to the accompanying drawings, in which:

FIG. 1 is an illustrative view showing a partial cross-section of an organic light-emitting diode display panel in prior art.

FIG. 2 is an illustrative view showing a partial cross-section of a color filter substrate according to an embodiment of the invention;

FIG. 3 is an illustrative view showing a comparison between light paths of display panels according to an embodiment of the invention and of the prior art, wherein an upper part of FIG. 3 shows the light path in the display panel of prior art, and a lower part of FIG. 3 shows the light path in the display panel according to the embodiment of the invention.

### DETAILED DESCRIPTION OF PREFERRED EMBODIMENTS

Exemplary embodiments of the present disclosure will be described hereinafter in detail with reference to the attached drawings, wherein the like reference numerals refer to the like elements. The present disclosure may, however, be embodied in many different forms and should not be construed as being limited to the embodiment set forth herein; rather, these embodiments are provided so that the present disclosure will be thorough and complete, and will fully convey the concept of the disclosure to those skilled in the art.

In the context, sentence “A is located above B” means that: A and B are located at the same side of a base substrate, and A is formed after a formation of B, such that A is certainly farther away from the base substrate than B in a direction perpendicular to the base substrate. Correspondingly, sentence “A is located on B” means that: A is not only farther away from the base substrate than B in a direction perpendicular to the base substrate, but also contacts B.

According to an aspect of the invention, there is provided a color filter substrate.

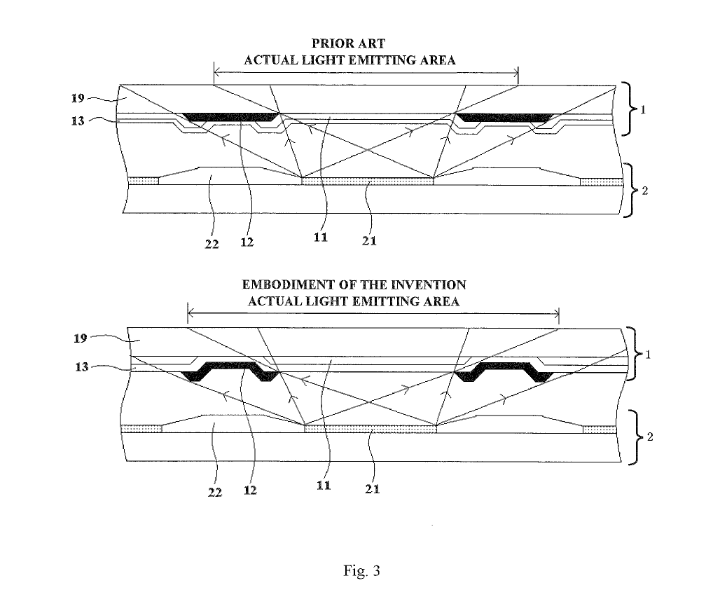

As shown in FIGS. 2 and 3, according to an embodiment, a color filter substrate 1 includes: a base substrate 19; a color filter 11 located on one side of the base substrate 19; and a black matrix 12 located on a side of the color filter 11 facing away from the base substrate 19. The black matrix 12 covers a portion of the color filter 11.

The color filter substrate 1 is used to be assembled with an array substrate 2 to obtain a display panel, and the color filter 11 is at least arranged at a position of the array substrate 2 corresponding to a respective pixel, such that light emitted from the pixel is converted into light having a desired color after passing through the color filter, while the black matrix 12 is arranged at a position corresponding to a gap between adjacent pixels.

Compared with the color filter substrate in prior art, in the color filter substrate 1 according to the embodiment, the black matrix 12 is formed after a formation of the color filter 11, thus, the black matrix 12 is disposed above the color filter 11, as shown in FIG. 2.

Although the black matrix 12 is formed after the formation of the color filter 11, it does not mean that all the portions of the black matrix 12 are farther away from the base substrate 19 than the color filter 11. For example, the black matrix 12 may include a portion that is overlapped with the color filter 11 and a portion that is not overlapped with the color filter 11, a distance between the portion of the black matrix 12 that is not overlapped with the color filter 11 and the base substrate 19 may be the same as a distance between the color filter 11 and the base substrate 19.

In the color filter substrate according to the embodiment, the black matrix 12 is located above the color filter 11, thus, at least a portion of the black matrix 12 is farther away from the base substrate 19 than the color filter 11. Therefore, in the case that all components have the same thicknesses and sizes, a distance between the portion of the black matrix 12 and the array substrate 2 is reduced. As shown in FIG. 3, an edge of each light-shielding portion of the black matrix 12 is disposed closer to the array substrate 2. In such a manner, as shown in FIG. 3, degree of an angle at which light emitted by the organic light-emitting diode 21 is shielded by the black matrix 12 on both sides thereof is increased, such that light emitted by the organic light-emitting diode 21 towards regions of the color filter 11 corresponding other pixels will be totally reflected much easier, and a range of an angle at which light emitted by the organic light-emitting diode 21 exits from the region of the color filter 11 corresponding to the organic light-emitting diode 21 is enlarged. Therefore, the color filter substrate 1 may prevent light leakage and light mixing by just changing a relative position of the black matrix and the color filter. Moreover, an actual light exiting area may be increased, and in turn, light exiting efficiency is improved, power consumption is reduced, and display quality is improved.

In an exemplary embodiment, the color filter substrate may include a plurality of color filters 11, and these color filters 11 may have at least two different colors. The color filters may be aligned respectively with a plurality of organic light-emitting diodes 21 arranged on the array substrate within a plurality of pixels.

That is to say, the color filter substrate may include a plurality of color filters 11 having a plurality of different colors, such as a red color filter, a blue color filter, a green color filter, and a yellow color filter that is used for adjustment of colour gamut. In this case, if light emitted by a certain light-emitting component enters a color filter having another color, an influence will be more obvious (i.e., light mixing occurs), thus, a color filter substrate according to the embodiment of the invention is needed to prevent the light mixing. In an exemplary embodiment, adjacent color filters 11 having different colors may have a gap therebetween, as shown in FIG. 3. The black matrix 12 may cover the gap and extend beyond the gap.

That is to say, as shown in FIG. 2, when there are a plurality of color filters 11 that have a plurality of colors, these color filters 11 of different colors are spaced apart by a gap, and the black matrix 12 covers the gap and at least portions of the color filters 11 at both sides of the gap.

In an embodiment that is not shown, color filters 11 having different colors may also be arranged without a gap therebetween, and in this embodiment, the color filters may be closely joined or overlapped with each other. In this case, the black matrix needs to be arranged at a junction between adjacent color filters and have a suitable area. In an exemplary embodiment, the color filter 11 may also include an overcoat or protective layer 13, which covers the color filter 11 but does not cover the black matrix. For example, the black matrix 12 may be located on a side of the protective layer 13 away from the base substrate 19.

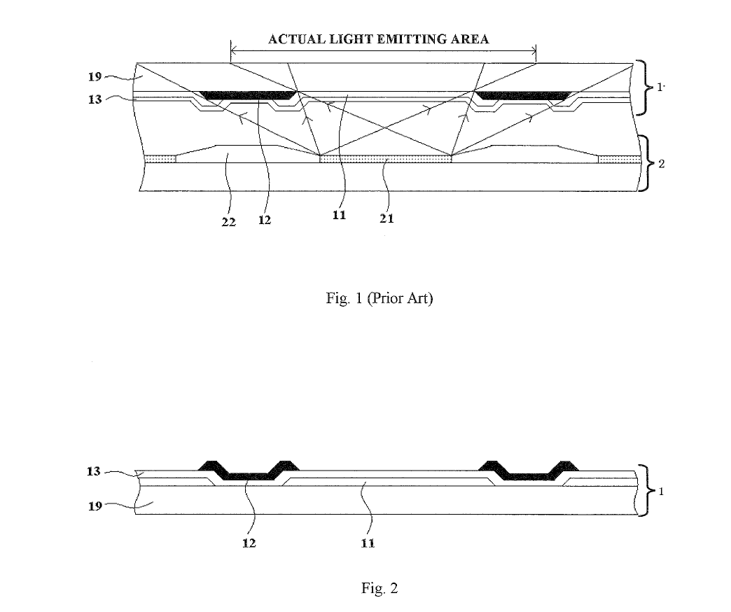

In prior art, for example, in the color filter 1 shown in FIG. 1, the protective layer 13 usually covers both the black matrix 12 and the color filter 11. In comparison, in the color filter substrate according to the embodiment of the invention, as shown in FIG. 2, the protective layer 13 only covers the color filter 11, and the black matrix 12 are located above the protective layer 13. That is to say, the black matrix 12 is not only above the color filter 11, but also above the protective layer 13. Thus, the distance between the black matrix 12 and the base substrate 19 is further increased, such that the black matrix 12 is disposed much closer to the array substrate 2, and in such a manner, light leakage may be prevented more efficiently and an actual light-emitting area of the color filter substrate corresponding to a respective pixel is also increased, as shown in FIG. 3.

In an embodiment that is not shown, the protective layer 13 may also cover both the color filter 11 and the black matrix 12.

Of course, in the color filter substrate 1, various known components or structures may be provided, and arrangement and formation of these components or structures are known and will not be described in detail.

According to another aspect of the invention, there is provided a display panel.

As shown in FIG. 3, the display panel include the color filter substrate 1 and the array substrate 2 arranged opposite to the color filter substrate 1. One side surface of the color filter substrate 1 provided with the black matrix 12 is arranged facing the array substrate 2, and the other side surface of the color filter substrate 1 is a light exiting surface of the display panel.

In an exemplary embodiment, the display panel may be an organic light-emitting diode (OLED) based display panel. The array substrate 2 includes an organic light-emitting diode 21 disposed at the side of the array substrate 2 facing the color filter substrate 1, and the organic light-emitting diode 21 is used for emitting light towards the color filter substrate 1.

As shown in FIG. 3, the light-emitting component (i.e., organic light-emitting diode 21) is located on inner side of the array substrate 2 and emits light towards the color filter substrate 1 directly. Thus, the arrangement of the black matrix 12 according the embodiment of the invention may prevent light leakage and enlarge the actual light exiting area in a better manner.

Specifically, a top-emission OLED display panel having a 160 ppi resolution is taken as an example, and an assumption is as follows: a light emitting surface of each OLED 21 on the array substrate 2 has a size of 36 μm×115 μm, the base substrate 19 of the color filter substrate 1 is a glass plate having a thickness of 0.7 mm, an opening in the material of the black matrix 12 corresponding the OLED 21 has a size of 41 μm×115 μm, the black matrix 12 has a thickness of 1.5 μm, the color filter 11 has a thickness of 2 μm, the protective layer 13 has a thickness of 2 μm, and an interval (gap) between the array substrate 2 and the color filter substrate 1 is 12 μm. In the case of prior art, the black matrix 12 is arranged below the color filter 11 and the protective layer 13, and it is determined through a calculation that an actual light-emitting area (opening ratio) is 46%. However, according to the embodiment of the invention, as shown in FIG. 3, the black matrix 12 is arranged above the color filter 11 and the protective layer 13, it is determined through a calculation that an actual light-emitting area (opening ratio) is 55%, which is about 9% higher than that in prior art. The above result may further prove the beneficial effect achieved by the embodiment of the invention.

For a top-emission OLED display panel, the color filter substrate 1 is also called as a “package substrate”, as it may enclose the organic light-emitting diodes 21 on the array substrate 2 within a sealed space formed between the color filter substrate 1 and the color filter substrate 1 with a sealing material, such that the organic light-emitting diodes 21 may be prevented from being influenced by outside moisture and oxygen. Since other functions and structure of the color filter substrate 1 are known in the field, a detailed description thereof is omitted.

In an exemplary embodiment, the array substrate 2 may also include a pixel defining layer 22, a gate line, a data line, an alignment mark and the like, and each organic light-emitting diode 21 may includes an anode, a cathode, a hole injection layer, a hole transport layer, a light-emitting layer, an electron transport layer, an electron injection layer and the like. Since these configurations are known in the field, a detailed description thereof is omitted.

Although the above embodiment are described by taking a top-emission OLED display panel as an example, the display panel may also be a bottom-emission OLED display panel, a liquid crystal display panel or the like, in which the color filter substrate 1 is configured such that one side surface thereof having the black matrix 12 faces the array substrate 2 and the other side surface thereof away from the array substrate 2 is used as a light exiting surface.

The display panel according to the embodiment of the invention may be used in an electronic book, a mobile phone, a tablet computer, a television, a display device, a notebook computer, a digital frame, a navigator and any product or component having a display function.

In another aspect of the invention, there is provided a method of manufacturing the color filter substrate.

In an exemplary embodiment, as shown in FIG. 2, the method comprises the following steps:

S1: forming a color filter 11 on a base substrate 19; and

S2: forming a black matrix 12 on the base substrate 19, such that the black matrix 12 covers a portion of the color filter 11.

Compared with prior art in which the color filter 11 is formed after the formation of the black matrix 12, in the embodiment of the invention, the black matrix 12 is formed after the formation of the color filter 11. In this manner, the black matrix 12 covers a portion of the color filter 11, such that after the display panel is formed, the black matrix 12 is disposed closer to the array substrate 12, which may efficiently prevent light leakage and improve light exiting efficiency.

Therefore, with the method according to the embodiment, a color filter substrate that is able to efficiently prevent light leakage can be obtained by simply changing a sequence of formations of the black matrix and of the color filter of the color filter substrate.

In an exemplary embodiment, the method may further comprise forming a protective layer 13. For example, the protective layer 13 may be formed after the formation of the color filter substrate 11 and before the black matrix 12 is formed, such that the protective layer 13 only protects the color filter substrate 11.

Alternatively, the protective layer 13 may be formed after the formation of the black matrix 12, such that the protective layer 13 protects both the color filter substrate 11 and the black matrix 12.

Steps of forming the above structure may be carried out with various kinds of known processes, such as coating, photoetching, screen printing, or the like. Additionally, before forming the above structure, alignment mark(s) or the like may be preformed. Since specific processes for forming the components of the color filter substrate 1 are known in the field, a detailed description thereof is omitted.

Although several exemplary embodiments have been shown and described, it would be appreciated by those skilled in the art that various changes or modifications may be made in these embodiments without departing from the principles and spirit of the disclosure, the scope of which is defined in the claims and their equivalents.

1. An color filter substrate, comprising:
a base substrate;
a first color filter located on a side of the base substrate; and
a black matrix located on a side of the color filter facing away from the base substrate,
wherein the black matrix covers a portion of the first color filter.

2. The color filter substrate according to claim 1, further comprising a second color filter, wherein the second color filter is arranged adjacent to the first color filter and has a color different from that of the first color filter.

3. The color filter substrate according to claim 2, wherein the first color filter and the second color filter are spaced apart from each other with a gap therebetween, and wherein the black matrix is configured to cover the gap and a portion of the second color filter.

4. The color filter substrate according to claim 1, further comprising a protective layer covering the first color filter, wherein the black matrix is located on a side of the protective layer away from the base substrate.

5. The color filter substrate according to claim 1, further comprising a protective layer covering the first color filter and the black matrix.

6. A display panel, comprising:
a color filter substrate according to claim 1; and
an array substrate disposed opposite to the color filter substrate,
wherein the color filter substrate is configured such that the side of the color filter substrate provided with the black matrix faces the array substrate and the other side of the color filter substrate opposite to the surface provided with the black matrix is a light exiting surface of the display panel.

7. The display panel according to claim 6, wherein the display panel comprises an organic light-emitting diode display panel, and wherein the array substrate comprises an organic light-emitting diode located on a side of the array substrate facing the color filter substrate and configured for emitting light towards the color filter substrate.

8. A method of manufacturing a color filter substrate, the method comprising:
providing a base substrate;
forming a color filter on a side of the base substrate; and
forming a black matrix on a side of the color filter facing away from the base substrate such that the black matrix covers a portion of the color filter.

9. The method according to claim 8, further comprising:
forming a protective layer after the color filter is formed and before the black matrix is formed.

10. The method according to claim 8, further comprising:
forming a protective layer after the black matrix is formed.
